(19) United States
(12) Patent Application Publication
(10) Pub. No.: US 2024/0170261 A1
(43) Pub. Date: May 23, 2024

(54) PLASMA GENERATOR FOR EDGE UNIFORMITY

(71) Applicant: Applied Materials, Inc., Santa Clara, CA (US)

(72) Inventors: Vladimir NAGORNY, Tracy, CA (US); Rene GEORGE, San Carlos, CA (US); Wei LIU, San Jose, CA (US)

(21) Appl. No.: 17/991,651

(22) Filed: Nov. 21, 2022

(51) Int. Cl. H01J 37/32

(52) U.S. Cl. CPC H01J 37/32385; H01J 37/32348; H01J 37/32568

(57) ABSTRACT

Embodiments of the present disclosure generally relate to a plasma processing apparatus. The plasma processing apparatus includes a processing chamber including a substrate support operable to hold a substrate, a main plasma source coupled with the processing chamber, a plate, a cavity, and an edge plasma generator. The cavity is housed within the plate and spaced radially outward from a dielectric sidewall of the main plasma source.

### BACKGROUND

### Field

Embodiments of the present disclosure generally relate to plasma generators, plasma processing apparatus, and methods of using the same. In particular, the present disclosure relates to enhanced plasma processing at the edge of a substrate.

### Description of the Related Art

Plasma processing is used in the semiconductor industry for deposition, etching, resist removal, and related processing of semiconductor substrates and other substrates. Plasma generates species with properties not achievable in other kind of processing—wet, thermal, etc. Plasma breaks atoms and molecules into radicals, generates ions which can be used to achieve one or the other capability required for the specific process. Usually, a mixture of gases is fed into plasma generation region, and electrons accelerated in a high electric field region ionize and dissociate this mixture, creating completely new gas, rich on radicals and ions.

Process uniformity affects the manufacturing yield and thus the cost of a semiconductor device. Typical process uniformity requirement in today's semiconductor manufacturing is around 1%-2% variation across the whole substrate, with exclusion of 1-3 mm from the edge, which raises the importance of the process control. These stringent constraints that continuously get firmer make researchers look for new methods for controlling process uniformity especially non-uniformities concentrated near the edge of the substrate, which relate to closeness of the chamber walls and details of RF antenna. Walls are responsible for recombination of species, gas temperature variations, flow pattern and other factors affecting fluxes on the substrate, especially near the edge of the substrate. In order to compensate for extra losses, one often uses another RF antenna (e.g. ICP coil) at the periphery of the chamber in addition to antenna (e.g. ICP coil) in the central region of the chamber.

Adding a larger coil (for ICP type of source) creates global effects resulting in different plasma behavior. As a result, the larger coil being utilized to correct the process uniformity at the edges of the substrate becomes the main coil and original antenna becomes a corrective one. The larger coil further requires higher power than the original antenna. This creates significant changes in the processing conditions of the whole substrate.

Therefore, there is a need for different plasma sources and plasma processing apparatus, and methods of using the same. In particular, there is a need for plasma processing at the edge of a substrate with no effect or minimum effect on the main region of the process.

### SUMMARY

Embodiments of the present disclosure generally relate to plasma processing methods.

In one embodiment, a plasma processing apparatus is disclosed. The plasma processing apparatus includes a processing chamber including a substrate support operable to hold a substrate, a main plasma source coupled with the processing chamber, a plate, a cavity, and an edge plasma generator. The cavity is housed within the plate and spaced radially outward from a dielectric sidewall of the main plasma source.

In another embodiment, a plasma processing apparatus is disclosed. The plasma processing apparatus includes a processing chamber including a substrate support operable to hold a substrate, a main plasma source coupled with the processing chamber, an edge plasma generator, a plate, and a cavity. The edge plasma generator includes a first electrode disposed within or adjacent to the cavity. The cavity is housed within the plate and spaced radially outward from the dielectric sidewall. The main plasma source includes an induction coil, a dielectric sidewall, a top cover; and a main plasma source interior defined by the dielectric sidewall and top cover.

In yet another embodiment, a plasma processing apparatus is disclosed. The processing chamber includes a substrate support operable to hold a substrate, a main plasma source coupled with the processing chamber, and an edge plasma generator. The main plasma source includes an induction coil, a dielectric sidewall, a top cover, a main plasma source interior defined by the dielectric sidewall and top cover, a plate, and a plurality of apertures housed within the plate and spaced radially outward from the dielectric sidewall. The edge plasma generator includes a first electrode disposed within or adjacent to the apertures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic diagram of an enhanced plasma processing apparatus, according to embodiments of the disclosure.

FIG. 2 is a schematic diagram of an alternative enhanced plasma processing apparatus, according to embodiments of the disclosure.

FIG. 3 is a schematic diagram of an alternative enhanced plasma processing apparatus, according to embodiments of the disclosure.

FIG. 4 is a schematic diagram of an alternative enhanced plasma processing apparatus, according to embodiments of the disclosure.

FIG. 5 is a schematic diagram of the plate having an inductively coupled plasma (ICP) edge plasma generator at a cut line 5-5, according to embodiments of the disclosure.

FIG. 6 is a schematic diagram of the plate having an ICP edge plasma generator at a cut line 6-6, according to embodiments of the disclosure.

FIG. 7 is a schematic diagram of the plate having a dielectric barrier discharge (DBD) edge plasma generator at a cut line 6-6, according to embodiments of the disclosure.

FIG. 8 is a schematic diagram of the plate having a capacitive coupled plasma (CCP) edge plasma generator at a cut line 5-5 according to embodiments of the disclosure.

FIG. 9 is a schematic diagram of the plate having a CCP edge plasma generator at a cut line 9-9, according to embodiments of the disclosure.

FIG. 10 is a schematic diagram of the plate having a CCP edge plasma generator at a cut line 9-9, according to embodiments of the disclosure.

FIG. 11 is a schematic diagram of the plate having a CCP edge plasma generator at a cut line 9-9, according to embodiments of the disclosure.

FIG. 12 is a schematic diagram of an electrode, according to embodiments of the disclosure.

FIG. 13 is a schematic cross-sectional portion of the plate having an alternative plasma generator at a cut line 5-5, according to embodiments of the disclosure.

FIG. 14 is a schematic cross-sectional portion of the plate having an alternative CCP edge plasma generator at a cut line 14-14, according to embodiments of the disclosure.

FIG. 15 is a schematic cross-sectional portion of the plate having an alternative DBD edge plasma generator at cut line 14-14, according to embodiments of the disclosure.

FIGS. 16A-16C are schematic views of the plate having an alternative ICP edge plasma generator having a Faraday shield, according to embodiments of the disclosure.

FIG. 17 is a flow diagram of a method for plasma processing a substrate with a plasma processing apparatus, according to embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to improved plasma generators and plasma processing systems. In particular, the present disclosure relates to enhanced plasma processing at the edge of a substrate. Generators and apparatus of the present disclosure can provide improved plasma uniformity for processing substrates in addition to efficient delivery of high-density neutral plasma species (e.g., unconventional species) to the substrates.

Aspects of the present disclosure are discussed with reference to a “substrate” or semiconductor wafer for purposes of illustration and discussion. Those of ordinary skill in the art, using the disclosures provided herein, will understand that the example aspects of the present disclosure can be used in association with any suitable semiconductor substrate or other suitable substrate. A “substrate support” refers to any structure that can be used to support a substrate.

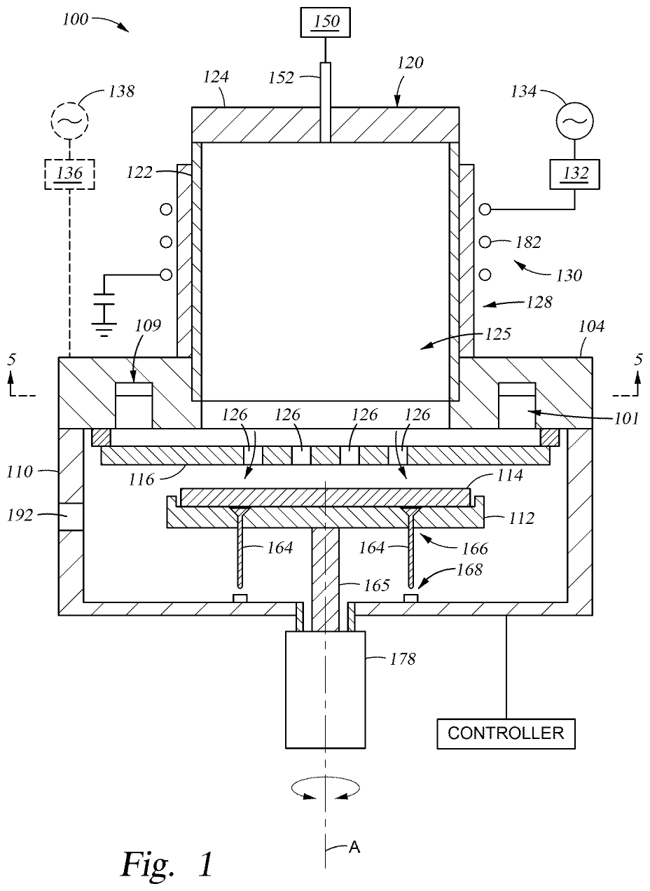

With reference now to the figures, example embodiments of the present disclosure will now be set forth. FIG. 1 depicts an example plasma processing apparatus 100. The plasma processing apparatus 100 includes a processing chamber 110, an edge plasma generator 109 embedded in a plate 104 and a main plasma source 120 (e.g., a remote plasma source) coupled with the processing chamber 110. The processing chamber 110 includes a substrate support 112 operable to hold a substrate 114. In some embodiments, the substrate has a thickness that is less than 1 mm. Substrate support 112 can be proximate one or more heat sources that provide heat to a substrate during processing of the substrate in the process chamber 110. Heat can be provided using any suitable heat source, such as one or more lamps, such as one or more rapid thermal processing lamps, or via a heated pedestal (e.g., a pedestal having resistive heating elements embedded therein or coupled thereto). In operation, the heat sources enable independent temperature control of the substrate.

A controller is coupled to the processing chamber 110, and may be used to control chamber processes described herein. In the illustrated embodiment, the substrate support 112 is disposed between a separation grid 116 and the bottom wall of the processing chamber 110. In another embodiment, there is no separation grid and the substrate support 112 is disposed between the plate 104 and the bottom wall of the processing chamber 110. A plurality of sensors can be disposed proximate the substrate support 112 for measuring the temperature within the processing chamber 110. The plurality of sensors can include one or more infrared pyrometers or miniature pyrometers. In certain embodiments, the one or more pyrometers includes 2, 3, or 4 pyrometers. In certain embodiments, the pyrometers have a wavelength of 3.3 μm, although in general, commercial pyrometer wavelengths typically vary from about 0.5 μm to about 14 μm. In some embodiments, the pyrometers are bottom pyrometers, meaning the pyrometers are positioned below the substrate.

The substrate support 112 is coupled with a shaft 165. The shaft may be connected to an actuator 178 that provides rotational movement of the shaft and substrate support (about an axis A). Actuator 178 may additionally or alternatively provide height adjustment of the shaft 165 during processing.

The substrate support 112 includes lift pin holes 166 disposed therein. The lift pin holes 166 are sized to accommodate a lift pin 164 for lifting of the substrate 114 from the substrate support 112 either before or after a deposition process is performed. The lift pins 164 may rest on lift pin stops 168 when the substrate 114 is lowered from a processing position to a transfer position.

A plasma can be generated in main plasma source 120 (e.g., in a plasma generation region) by induction coil 130 and desired particles flow from the main plasma source 120 to the surface of substrate 114 through holes 126 provided in a separation grid 116 that separates the main plasma source 120 from the processing chamber 110 (a downstream region).

The main plasma source 120 includes a dielectric sidewall 122. The main plasma source 120 includes a top cover 124. The dielectric sidewall 122 and top cover 124 define a plasma source interior 125. Dielectric sidewall 122 can include any suitable dielectric material, such as quartz or alumina. An induction coil 130 is disposed proximate (e.g., adjacent) the dielectric sidewall 122 about the main plasma source 120. The induction coil 130 includes a plurality of coil loops including coil loop 182. The induction coil 130 is coupled to power supply 134 through any suitable matching network 132. In some embodiments, the power supply 134 may be a RF power supply. Feed gases are introduced to the plasma source interior from a gas supply 150 through a gas inlet 152. When the induction coil 130 is energized with RF power from the power supply 134, a plasma is generated in the main plasma source 120. In some embodiments, RF power is provided to coil 130 at about 0.5 KW to about 15 KW, such as about 1 kW to about 10 KW. Induction coil 130 may ignite and sustain a plasma in a wide pressure and flow range. In some embodiments, the plasma processing apparatus 100 includes a grounded Faraday shield 128 to reduce capacitive coupling of the induction coil 130 to the plasma. The grounded Faraday shield can include any suitable conductive material, such as aluminum or an aluminum alloy.

A plasma can be generated in the edge plasma generator 109. The edge plasma generator 109 is configured to radially surround the main plasma source 120 and provide independent plasma processing near an edge of the substrate 114 while the substrate 114 is in the processing position. The edge plasma generator 109 is adjacent to a cavity 101. In one embodiment, the edge plasma generator 109 is coupled to the power supply 134 through any suitable matching network 132. When the edge plasma generator 109 is energized with RF power from the power supply 134, a plasma is generated at the edge of the substrate 114. In another embodiment, the edge plasma generator 109 is coupled to a second power supply 138 through any suitable second matching network 136. In some embodiments, the second power supply 138 is a RF power generator. When the edge plasma generator 109 is energized with RF power from the second power supply 138, a plasma is generated at the edge of the substrate 114.

In some embodiments, a separation grid 116 is configured to separate a processing chamber 110 area from plasma charged particles (ions and electrons), which recombine on the grid, so that only neutral plasma species can pass through the separation grid 116 into the processing chamber 110. In some embodiments, separation grid 116 is formed of aluminum, anodized aluminum, quartz, aluminum nitride, aluminum oxide, tantalum, tantalum nitride, titanium, titanium nitride, or combination(s) thereof. For example, AlN can be beneficial for flux of nitrogen radicals, whereas conventional separation grids are more prone to nitrogen radical recombination. Similarly, aluminum oxide can provide flux of oxygen or hydrogen radicals, whereas conventional separation grids are more prone to their recombination. In some embodiments, the separation grid has a plurality of holes.

Slit valve opening 192 is coupled with a sidewall of process chamber 110. The slit valve opening is configured to allow for the substrate 114 to be moved in and out of the processing chamber 110 when the substrate 114 is in the transfer position. In one embodiment, the process chamber includes a process chamber 110 includes exhaust chamber to exhaust the feed gas.

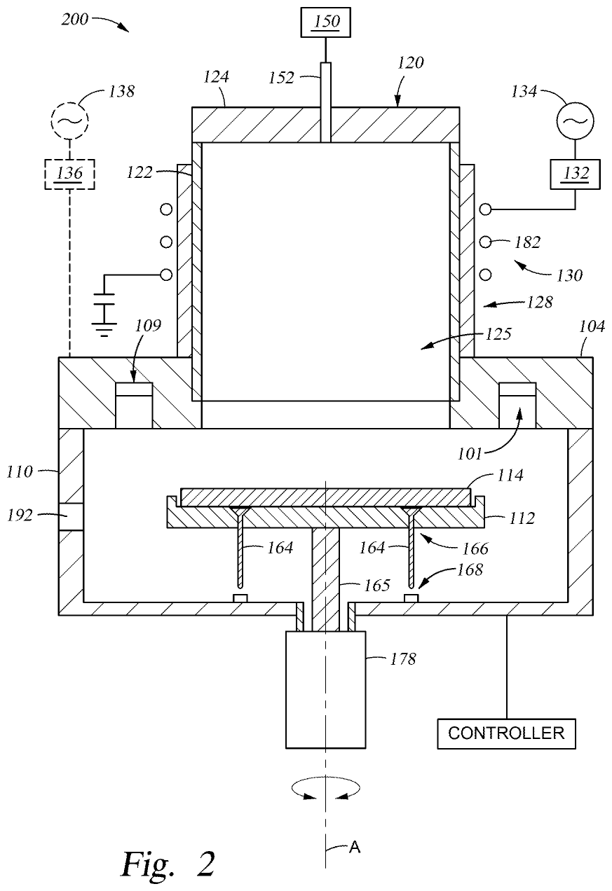

FIG. 2 is a schematic diagram of an alternative enhanced plasma processing apparatus 200. The alternative enhanced plasma processing apparatus 200 is similar to the enhanced plasma processing apparatus 100, but the enhanced plasma processing apparatus 200 does not include a separation grid 116 between the main plasma source 120 and the processing chamber 110. Similar reference numbers, therefore, are used to represent similar elements.

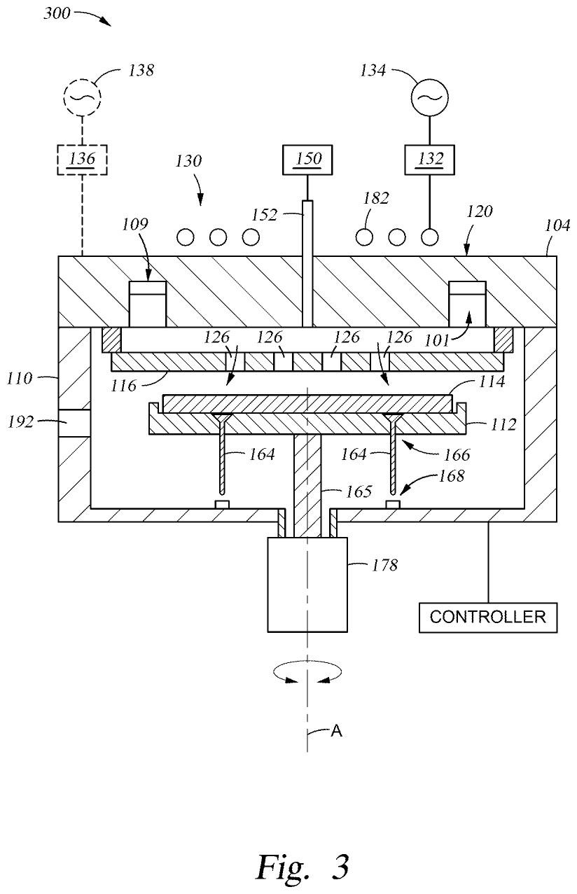

FIG. 3 is a schematic diagram of an alternative enhanced plasma processing apparatus 300. The alternative enhanced plasma processing apparatus 300 is similar to the enhanced plasma processing apparatus 100, but the enhanced plasma processing apparatus 300 has a horizontal main plasma source 120 over a processing chamber 110. Similar reference numbers, therefore, are used to represent similar elements.

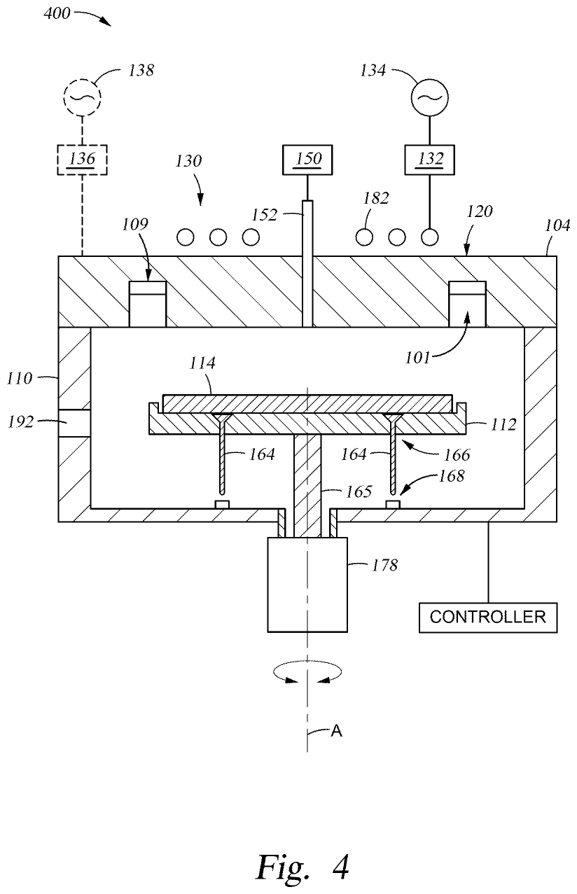

FIG. 4 is a schematic diagram of an alternative enhanced plasma processing apparatus 400. The alternative enhanced plasma processing apparatus 400 is similar to the enhanced plasma processing apparatus 300, but the enhanced plasma processing apparatus 400 does not include a separation grid 116 between the main plasma source 120 and the processing chamber 110. Similar reference numbers, therefore, are used to represent similar elements.

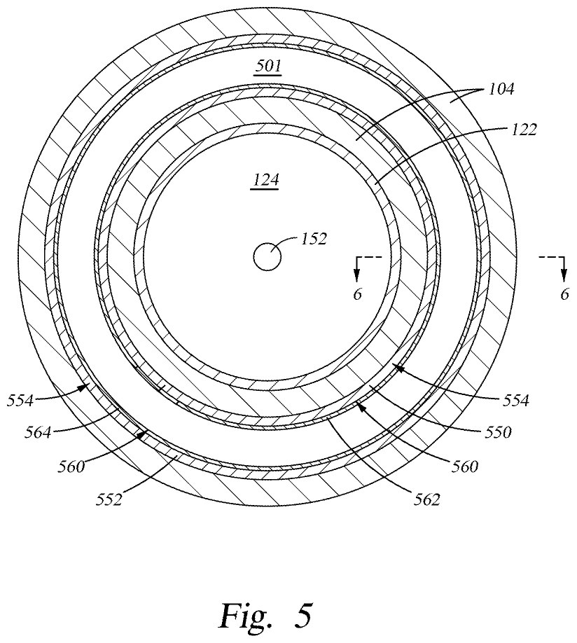

FIG. 5 is a schematic diagram of the plate 104 having the edge plasma generator 109 at a cut line 5-5. A cavity 501 that is housed within the plate 104. In one embodiment, the plate 104 is grounded. The cavity 501 may be used in place of the cavity 101. The cavity 501 is spaced radially outward from the dielectric sidewall 122. The plate 104 further includes a field concentrator 554 and an insulator (e.g., ceramic window 560). The field concentrator 554 includes an inner side portion 550 and an outer side portion 552. The inner side portion 550 is disposed radially inward from the cavity 501, and the outer side portion 552 is spaced radially outward from the cavity 501. The ceramic window 560 further includes an inner side portion 562 and an outer side portion 564. The inner side portion 562 is spaced radially inward from the cavity 501 and radially outward from the inner side portion 550 of the field concentrator 554. The outer side portion 564 is spaced radially outward from the cavity 501 and radially inward from the outer side portion 552 of the field concentrator 554.

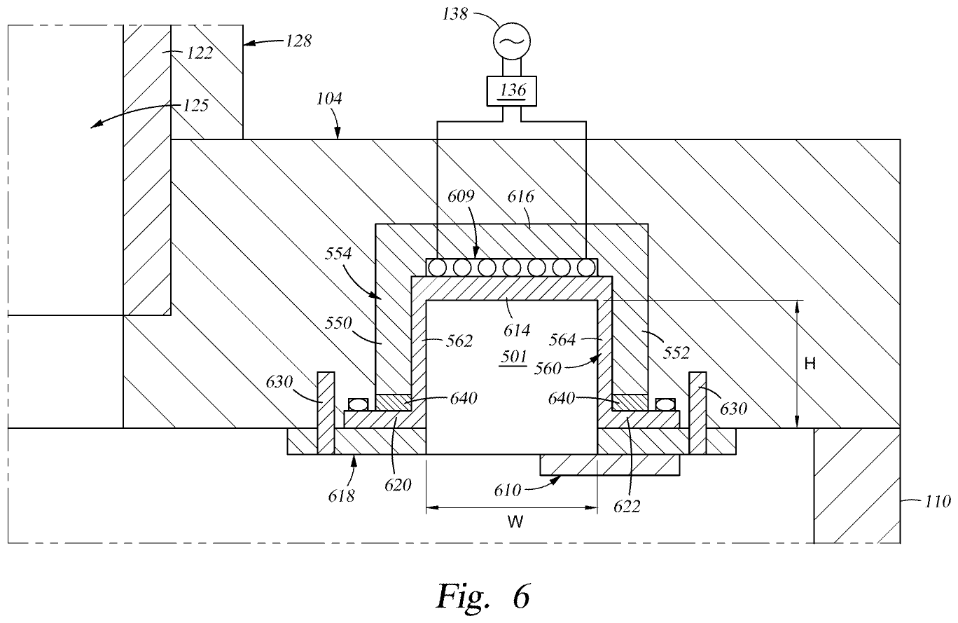

FIG. 6 is a schematic diagram of the plate 104 having the edge plasma generator 109 at a cut line 6-6. The edge plasma generator 109 further includes the field concentrator 554, an edge coil 609, a flux reducer 610, and the ceramic window 560. The edge coil 609 may be used in place of the edge plasma generator 109. The cavity 501 is defined on top and on the sides by the ceramic window 560. The cavity 501 includes a width W and a height H. The height H may be greater than about one quarter (¼) the width W and less than about 2 times the width W (e.g., ¼<H/W<4). The ceramic window 560 is surrounded by on the top and sides by the field concentrator 554. In one embodiment, the field concentrator 554 includes a ferromagnetic material, such as Ferrotron F559H for a frequency range below 3 MHz or 4C65 for higher frequency ranges. The ferromagnetic material may be any material with a permeability (u) greater than 10 and low dissipation at appropriate frequencies. The edge coil 609 is positioned between a top portion 614 of the ceramic window 560 and a top portion 616 of the field concentrator 554. The field concentrator 554 has disposed radially around the dielectric walls on the plasma side. The dielectric walls include materials such as alumina ceramics. In one embodiment, the edge coil 609 uses the second power supply 138 of between about 1 MHz and about 15 MHZ, such as about 2 MHz. Due to the design of the edge plasma generator 109, the edge coil 609 is capable of sustaining a plasma using relatively low power. The second power supply 138 is coupled to the edge plasma generator 109 through any suitable second matching network 136. In another embodiment, the power supply 134 is coupled to the edge plasma generator 109 through any suitable matching network 132.

The ceramic window 560 and field concentrator 554 are secured in the plate 104 by supports 618. An inner side flange 620 and an outer side flange 622 of the ceramic window 560 are disposed over a top surface of the supports 618. The inner side portion 550 and the outer side portion 552 of the field concentrator 554 are disposed over a top surface of the inner side flange 620 and outer side flange 622, respectively. In one embodiment, a washer 640 is disposed between the inner side portion 550 and the inner side flange 620 and between the outer side portion 552 and the outer side flange 622. The washer 640 may include aluminum or stainless steel. The washer 640 allows for more control over the plasma formed within the edge plasma generator 109. The supports 618 are secured to the plate 104 using anchors 630. The anchors 630 may include rivets, bolts, screws, or other fastening components. The flux reducer 610 is positioned below the supports 618 and the cavity 501. The flux reducer 610 works in addition to power control, allowing for the edge flux produced between the edge coil 609 and the substrate 114 to be reduced beyond the minimum flux generated by the edge coil 609. The flux reducer 610 may cover a portion of the width W of the cavity 510 or the entirety of the width W of the cavity 501. The flux reducer may include any suitable dielectric material or metal, such as aluminum, an aluminum alloy, or alumina.

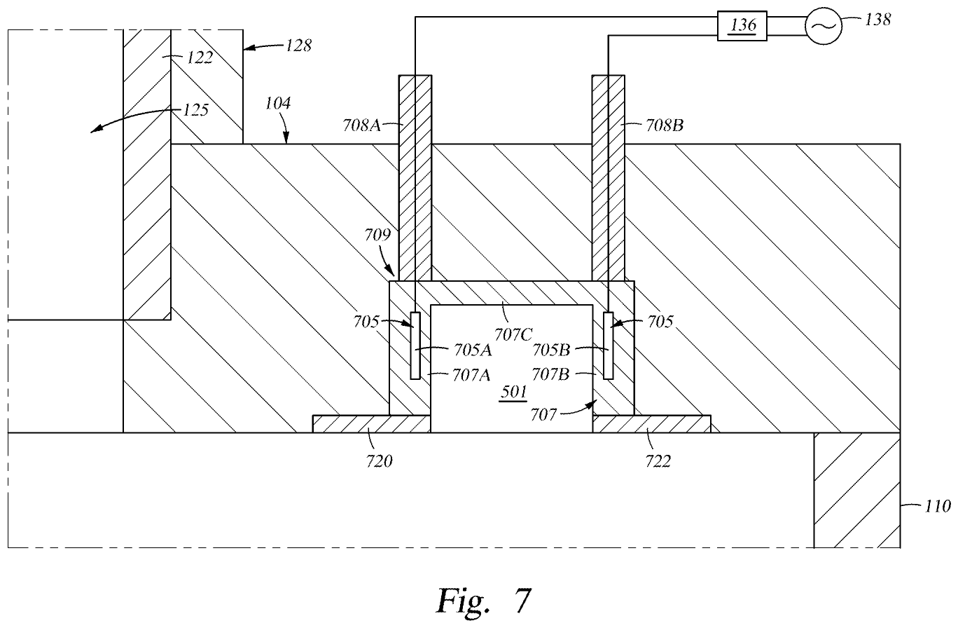

FIG. 7 is a schematic diagram of the plate 104 having a dielectric barrier discharge (DBD) edge plasma generator 709 at a cut line 6-6. The DBD edge plasma generator 709 may be used in place of edge plasma generator 109. The cavity 501 is embedded in the plate 104. The DBD edge plasma generator 709 includes a plurality of electrodes 705 (e.g., a first electrode 705A and a second electrode 705B). The cavity 501 is spaced radially outward from the main plasma source 120 near the edge of the substrate 114. In one embodiment, the cavity 501 is defined on top and on the sides by a cavity conduit 707 having an inner side portion 707A, an outer side portion 707B, and a top portion 707C. The first electrode 705A and the second electrode 705B are embedded in the cavity conduit 707. The cavity conduit 707 is disposed on an inner side flange 720 and an outer side flange 722.

The dielectric barrier discharge (DBD) edge plasma generator 709 is used as a high pressure plasma generator, e.g., for use between about 0.5 Torr and about 10 Torr. The DBD edge plasma generator 709 is a pulsed discharge with ignition in every pulse. Every ignition has high voltage across the discharge gap. In order to reduce driving (e.g., applied) voltage from the second power supply 138, the DBD edge plasma generator 709 can use dual side driving. The second power supply 138 is coupled to the electrodes 705A 705B of the DBD edge plasma generator 709 through any suitable second matching network 136. In another embodiment, the DBD edge plasma generator 709 is coupled to the power supply 134 through any suitable matching network 132. A first connection and a second connection from the first electrode 705A and the second electrode 705B to the power supply are covered in a first coating 708A and a second coating 708B, respectively. The plurality of electrodes 705 are insulated from the plasma using the cavity conduit 707, first coating 708A, and second coating 708B. In one embodiment, the cavity conduit 707, first coating 708A, second coating 708B, inner side flange 720 and outer side flange 722 include a dielectric material. The dielectric material includes any suitable dielectric material, such as alumina, or other material.

The DBD edge plasma generator 709 has a wide range and simple control over the discharge power. The power in the DBD edge plasma generator 709 is proportional to the frequency of the power supply, which in the frequency range for the DBD edge plasma generator 709 is easy to control. In one embodiment, the DBD edge plasma generator 709 has electrodes 705 placed on the same or adjacent surfaces rather than opposite surfaces.

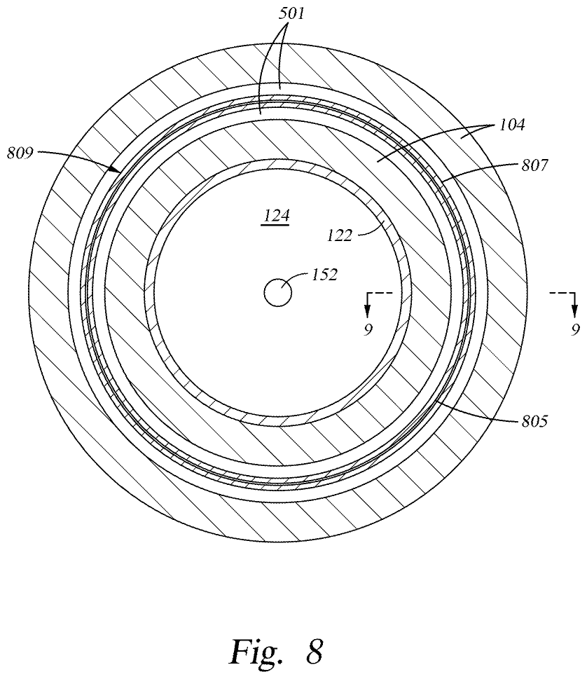

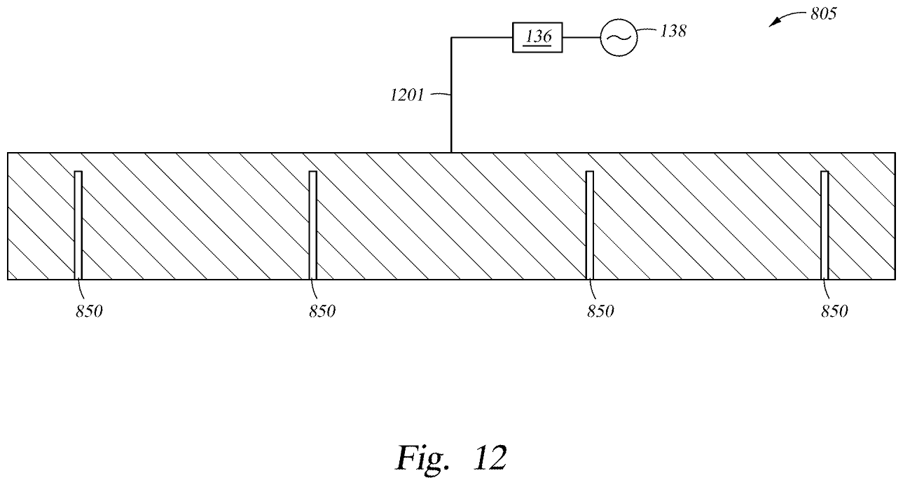

FIG. 8 is a schematic diagram of the plate 104 having a capacitive coupled plasma (CCP) edge plasma generator 809 at a cut line 5-5. The CCP edge plasma generator 809 may be used in place of edge plasma generator 109. The CCP edge plasma generator 809 includes an electrode 805. The electrode 805 may further include a series of cuts 850 as shown in FIG. 12.

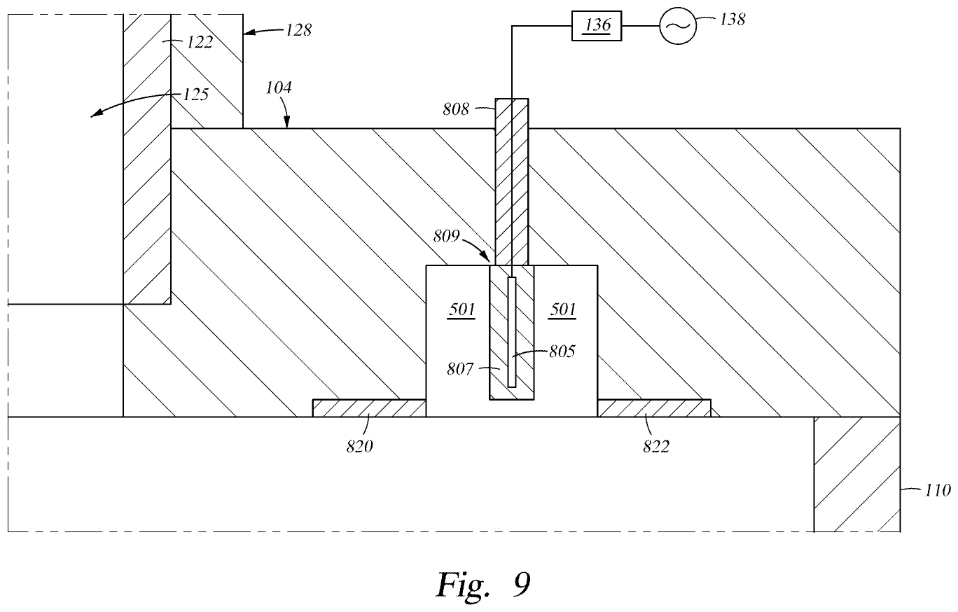

FIG. 9 is a schematic diagram of the plate 104 having a CCP edge plasma generator 809 at a cut line 9-9. The electrode 805 is in the middle of the cavity 501 (e.g., spaced from the sidewalls of the cavity 501). A portion of a wire is covered in a coating 808. The coating has a thickness between about 0.5 mm and about 2 mm. The electrode 805 is covered in the cavity conduit 807. The second power supply 138 is coupled to the CCP edge plasma generator 809 through any suitable second matching network 136. The wire connects the electrode 805 of the CCP edge plasma generator 809 to the power supply. In one embodiment, the plate 104 of the CCP edge plasma generator 809 further includes a dielectric flange on the inner side of the cavity and the outer side of the cavity (e.g., an inner side flange 820 and an outer side flange 822). The inner side flange 820 is radially inward from the cavity 501. In one embodiment, the inner side flange is adjacent to the cavity 501 (e.g., the outer edge of the inner flange 820 has a radius equal to the radius of the inner edge of the cavity 501). The outer side flange 822 is radially outward from the cavity 501. In one embodiment, the outer side flange is adjacent to the cavity 501 (e.g., the outer edge of the cavity 501 is equal to the radius of the inner edge of the outer side flange 822). In one embodiment, the coating 808, cavity conduit 807, the inner side flange 820 and outer side flange 822 include a dielectric material. The dielectric material may include a ceramic material such as alumina, zirconia, yttria, or other materials capable of withstanding plasma conditions.

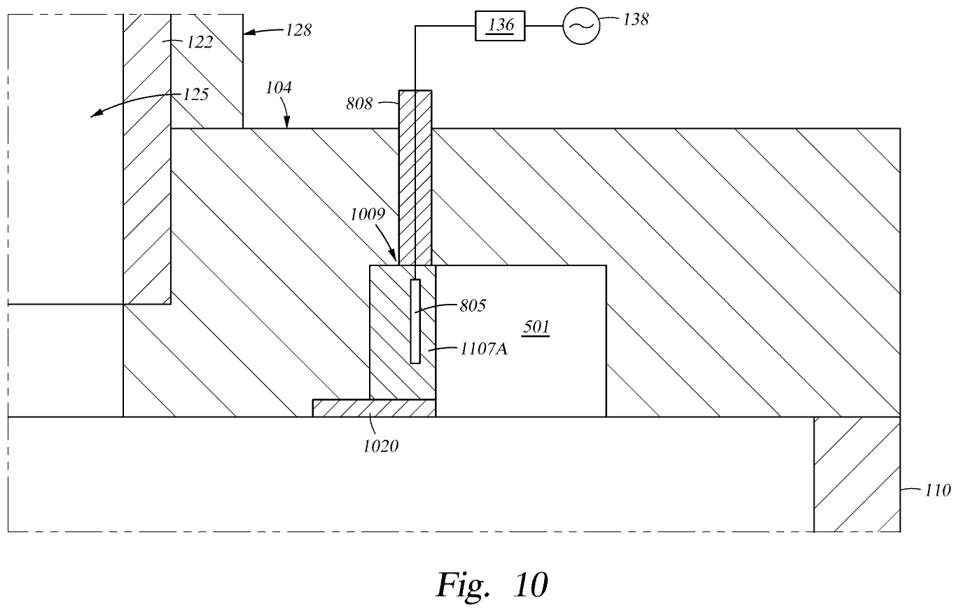

FIG. 10 is a schematic diagram of the plate 104 having a CCP edge plasma generator 1009 at a cut line 9-9. The CCP edge plasma generator 1009 may be used in place of edge plasma generator 109. The second power supply 138 is coupled to the CCP edge plasma generator 1009 through any suitable second matching network 136. In one embodiment, a wire connecting an electrode 805 of the CCP edge plasma generator 1009 is covered in a coating 808. In one embodiment, the cavity 501 is defined by an inner sidewall 1007A of the CCP edge cavity 1002. The electrode 805, in one embodiment, is covered by an inner sidewall 1007A. The inner sidewall 1007A is disposed on an inner side flange 1020. The thickness of the inner sidewall 1007A between the electrode 805 and the cavity 501 is thinner than the thickness of the inner sidewall 1007A between the electrode and the plate 104. The inner side flange 1020 is radially inward from the cavity 501. The inner sidewall 1007A, coating 808, and inner side flange 1020 include a dielectric material. The inner sidewall 1007A includes materials such as a ceramic material, such as alumina or yttria ceramics. The coating 808 includes a material with high dielectric strength, such as a ceramic, Teflon, or Ultem material. The inner side flange 1020 includes a material such as a ceramic material, such as alumina or yttria ceramics.

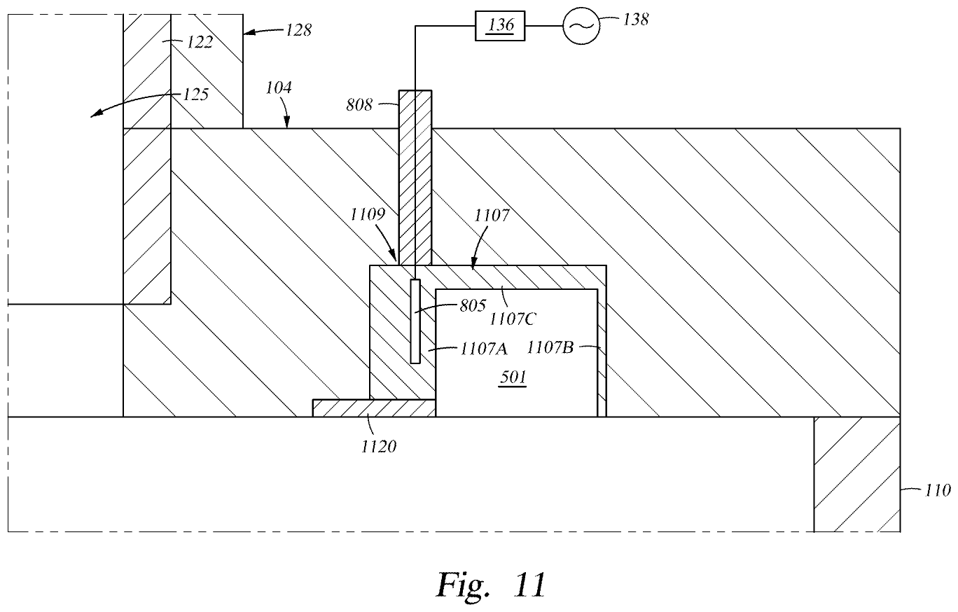

FIG. 11 is a schematic diagram of the plate 104 having a CCP edge plasma generator 1109 at a cut line 9-9. The CCP edge plasma generator 1109 may be used in place of edge plasma generator 109. The second power supply 138 is coupled to the CCP edge plasma generator 1109 through any suitable second matching network 136. The CCP edge plasma generator 1109 differs from the CCP edge plasma generator 1009 by having the cavity 501 defined by an inner sidewall 1107A, an outer sidewall 1107B, and a top portion 1107C. The inner sidewall 1107A, the outer sidewall 1107B, and a top portion 1107C protect the plasma generated in the CCP edge plasma generator 1109 from the metal sputtered from the walls of the cavity 501. The inner sidewall 1107A and outer sidewall 1107B have a thickness of about 0.1 mm to about 2 mm. The CCP edge plasma generator 1109 includes an electrode 805 embedded in the inner sidewall 1107A. A wire connects the electrode 805 of the CCP edge plasma generator 1109 to the power supply. The wire is coated in a coating 808. The thickness of the inner sidewall 1107A between the electrode 805 and the cavity 501 is thinner than the thickness between the electrode 805 and the plate 104. In one embodiment, the top portion 1107C has a thickness that is greater than the inner sidewall 1107A and the outer sidewall 1107B. The top portion 1107C has a thickness of about 3 mm to about 6 mm. The relationship between the thicknesses of the top portion 1107C, the inner sidewall 1107A, and the outer sidewall 1107B forces the current from the CCP edge plasma generator 1109 from the electrode 805 through the inner sidewall 1107A and outer sidewall 1107B towards the cavity. In one embodiment, the cavity conduit 1107, coating 1108, and inner side flange 1120 include a dielectric material. The inner sidewall 107A includes materials such as a ceramic material, such as alumina or yttria ceramics. The coating 808 includes a material with high dielectric strength, such as a ceramic, Teflon, or Ultem material. The inner side flange 1020 includes a material such as a ceramic material, such as cavity conduit 1107 alumina or yttria ceramics.

In another embodiment, the CCP edge plasma generators 809, 1009, and 1109 may be coupled to the power supply 134 through any suitable matching network 132.

FIG. 12 is a schematic diagram of the electrode 805 in an uncoiled, flat position. The electrode 805 includes the cuts 850. The cuts 850 are made around the electrode 805 in order to reduce hot spots caused by azimuthal instability. The cuts 850 are made along the circular electrode 805 every about 10° to about 45° to cut the electrode 805 into smaller electrodes with the gap in the azimuthal direction. The cuts 850 are about 20 mm to about 100 mm apart. Each cut 850 is approximately about 1 mm to about 2 mm in width. Power is supplied to the electrode using a terminal 1201.

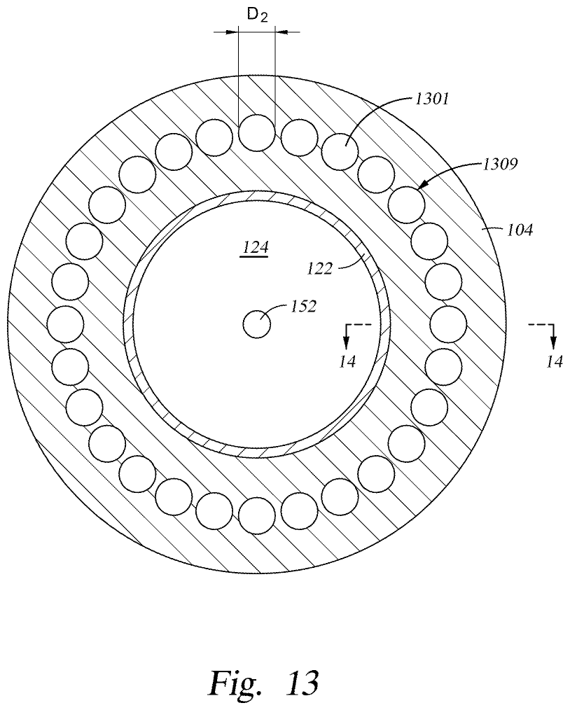

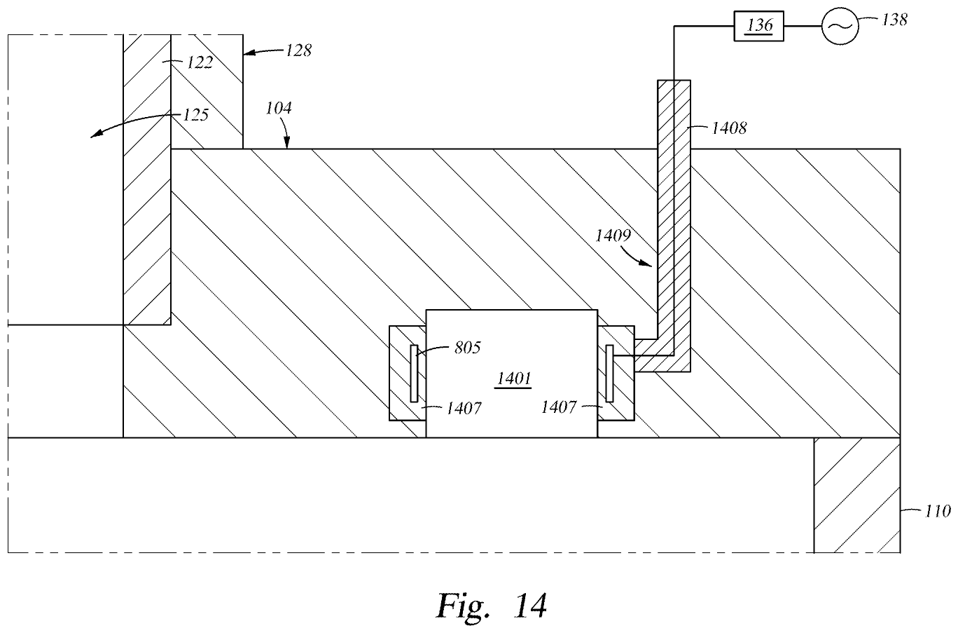

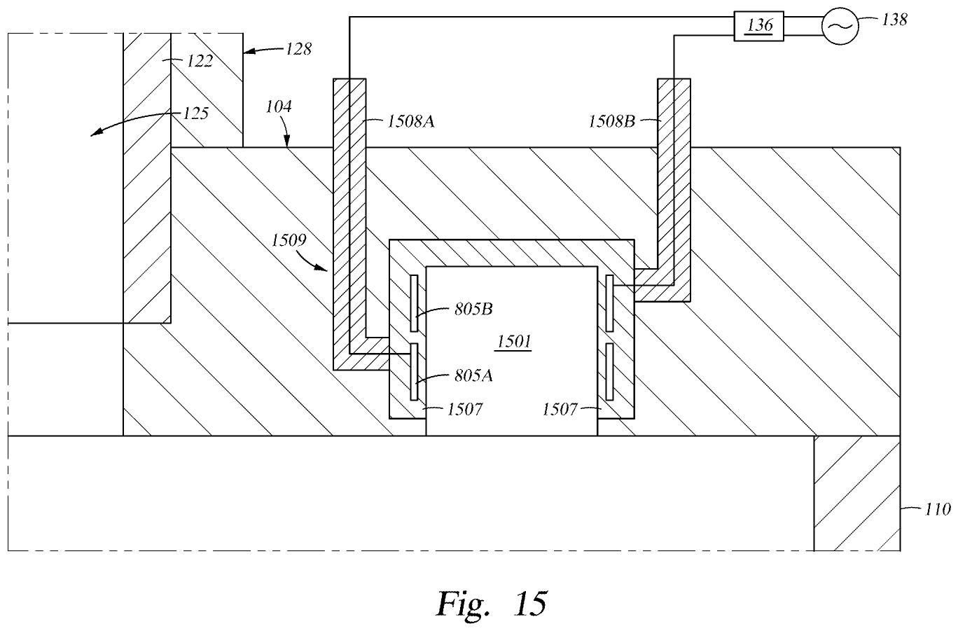

FIG. 13 is a schematic cross-sectional portion of the plate 104 having an alternative edge plasma generator 1309. The alternative edge plasma generator 1309 comprises a plurality of apertures 1301. The apertures 1301 may be used in place of the cavity 501. The apertures have a diameter D₂ approximately equal to the width of the cavity 501, e.g., between about 10 mm to about 30 mm. One or more electrodes 805 are positioned on a circumference of the apertures 1301, as shown in FIG. 14 for the CCP edge plasma generator and FIG. 15 for the DBD edge plasma generator.

FIG. 14 is a schematic cross-sectional portion of the plate 104 having an alternative CCP edge plasma generator 1409 at cut line 14-14. The alternative CCP edge plasma generator 1409 comprises CCP apertures 1401. The CCP apertures 1401 can be used in place of the apertures 1301 in the alternative edge plasma generator 1309. The second power supply 138 is coupled to the alternative CCP edge plasma generator 1409 through any suitable second matching network 136. In another embodiment, the alternative CCP edge plasma generator 1409 is coupled to the power supply 134 through any suitable matching network 132. The alternative CCP edge plasma generator 1409 includes a circular electrode 805. A wire is surrounded by an insulator (e.g., a coating 1408) and connects an electrode 805 of the alternative CCP edge plasma generator 1409 to the power supply. An electrode conduit 1407 radially surrounds the aperture 1401. The electrode 805 radially surrounds the CCP aperture 1401 within the electrode conduit 1407. In one embodiment, the top of the CCP aperture 1401 and portions of the sides of the CCP aperture 1401 are defined by the plate 104. The plate 104 is connected to ground. The electrode conduit 1407 and the coating 1408 include a dielectric material. The electrode conduit 1407 includes materials such as a ceramic material, such as alumina or yttria ceramics. The coating 1408 includes a material with high dielectric strength, such as a ceramic or Teflon material, such as alumina or yttria ceramics. The thickness of the electrode conduit 1407 between the electrode 805 and the aperture 1401 is thinner than the thickness of the electrode conduit 1407 between the electrode 805 and the plate 104.

FIG. 15 is a schematic cross-sectional portion of the plate 104 having an alternative DBD edge plasma generator 1509 at cut line 14-14. The alternative DBD edge plasma generator 1509 comprises DBD apertures 1501. The DBD apertures 1501 can be used in place of the apertures 1301 in the alternative edge plasma generator 1309. The second power supply 138 is coupled to the alternative DBD edge plasma generator 1509 through any suitable second matching network 136. The alternative DBD edge plasma generator 1509 includes a first circular electrode 805A and second circular electrode 805B. A first wire is surrounded by a first insulator (e.g., a first coating 1508A). A second wire is surrounded by a second insulator (e.g., a second coating 1508B). An electrode conduit 1507 radially surrounds a portion of the DBD aperture 1501. A first electrode 805A and a second electrode 805B radially surround the DBD aperture 1501 within the electrode conduit 1507. A top portion 1510 of the electrode conduit 1507 defines the top of the DBD aperture 1501. In one embodiment, a portion of the DBD aperture 1501 is defined by the plate 104, which is connected to ground. In one embodiment, the electrode conduit 1507, first coating 1508A, second coating 1508B, and top portion 1510 include a dielectric material. The electrode conduit 1507 includes materials such as a ceramic material, such as alumina or yttria ceramics. The first coating 1508A and second coating 1508B include a material with high dielectric strength, such as a ceramic or Teflon material.

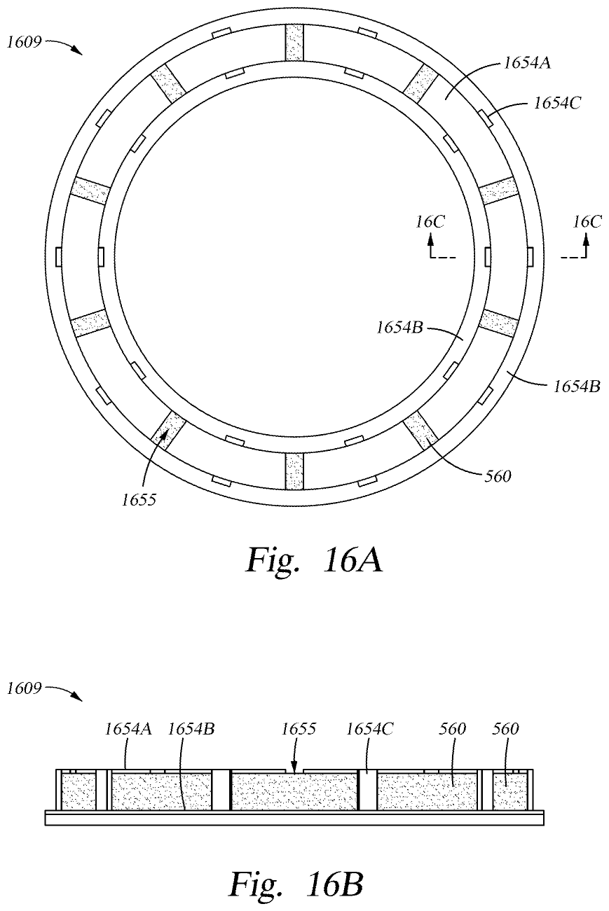

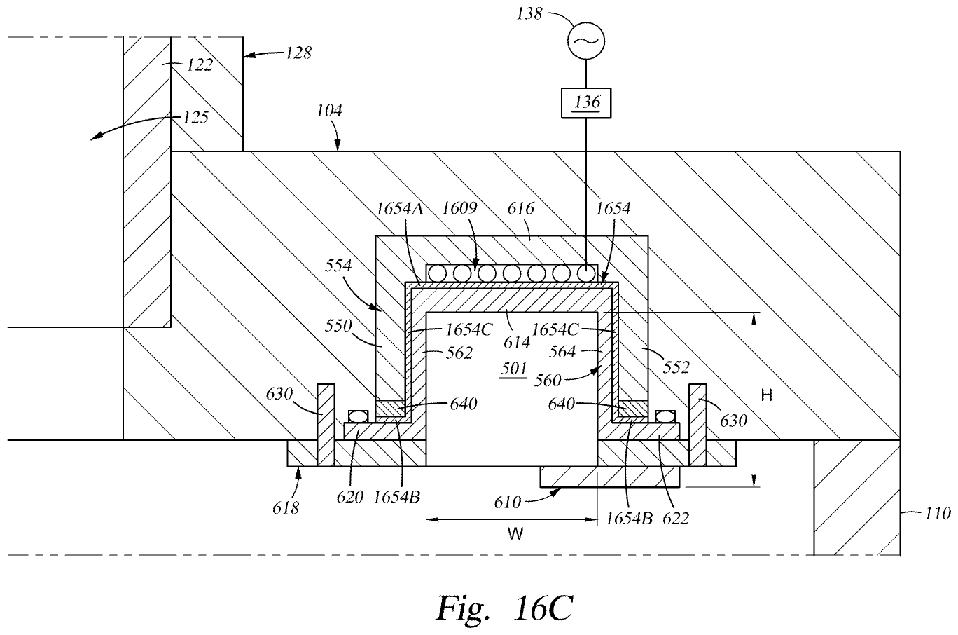

FIG. 16A is a schematic top plan view of an alternative ICP edge plasma generator 1609 with a Faraday shield. The plate 104 is removed for clarity. FIG. 16B is a schematic side view of an alternative ICP edge plasma generator 1609. FIG. 16C is a schematic cross-sectional view of the plate 104 having an alternative ICP edge plasma generator 1609 at cut line 16C-16C. The alternative ICP edge plasma generator 1609 differs from the ICP edge plasma generator 109 by having a Faraday shield, e.g., a metal film 1654. The ceramic window 560 is surrounded by on the top and sides by the metal film 1654. The metal film 1654 consists of a top layer 1654A, a base layer 1654B, and a plurality of connectors 1654C. The top layer 1654A is disposed over a top portion 614 of the ceramic window 560 and the base layer is disposed over an inner side flange 620 and an outer side flange 622 of the ceramic window 560. The plurality of connectors 1654C span between the top layer 1654A and the base layer 1654B along an inner side portion 562 of the ceramic window 560 and an outer side portion 564 of the ceramic window 560. In one embodiment, the alternative ICP edge plasma generator 1609 includes a ferromagnetic material with a frequency range below 3 MHZ. The ferromagnetic material may be any material with a permeability (u) greater than 10, such as Ferrotron F559H for a frequency range below 3 MHz or 4C65 for higher frequency ranges. The ferromagnetic material may be any material with a permeability (u) greater than 10 and low dissipation at appropriate frequencies. The alternative ICP edge plasma generator 1609 includes an edge coil that is positioned above a top portion 614 of the ceramic window 560 and a top layer 1654A of the metal film 1654.

The top layer 1654A of the metal film 1654 further contains a plurality of gaps 1655. The gaps 1655 are periodically spaced around over the top portion 614 of the ceramic window 560. The gaps 1655 allow the magnetic field produced from the alternative ICP edge plasma generator 1609 to penetrate the cavity 501. The top layer 1654A is capacitively coupled to the alternative ICP edge plasma generator 1609, preventing capacitive coupling between the alternative ICP edge plasma generator 1609 and the plasma. This is due to the top layer 1654A being connected to equipotential (grounded) base layer 1654B. The RF magnetic field freely penetrates the ceramic window 1660 to the cavity 1601 through the openings between the plurality of connectors 1654C. In another embodiment, a Faraday shield can be created using just the top layer 1654A, the base layer 1654B, and a plurality of connectors 1654C on one side (inner or outer) of the ceramic window 1660.

Although all edge plasma generators shown in FIG. 1-16 have a may have a simple square shape with straight walls of the same height and thickness, it is within the scope of this disclosure that the shape of the edge plasma generators may have different heights, thicknesses, and shapes.

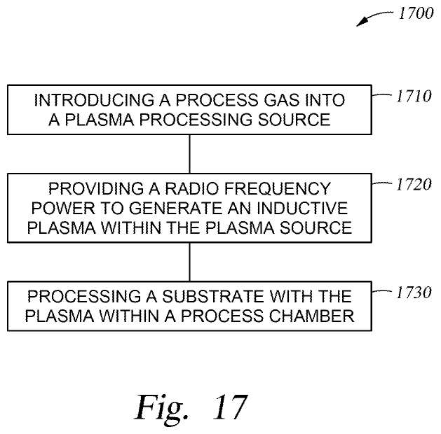

FIG. 17 is a flow diagram of a method 1700 for plasma processing a substrate with a plasma processing apparatus of the present disclosure. At operation 1710, a process gas is introduced into a plasma processing source. The process gas and flow rate thereof may be selected based on a particular substrate processing application. In general, the process gas may include at least one of N₂, NH₃, O₂, H₂, or He, and the flow rate may be about 1000 sccm to about 30000 sccm. However, other process gases and other flow rates (both higher and lower) are contemplated within the scope of this disclosure. At operation 1720 a radio frequency power is provided to generate an inductive plasma within the plasma generator. The radio frequency power may be controlled based on the particular substrate processing application. In general, the radio frequency power may be about 1 kW to about 10 KW, however other power levels are also contemplated. From an interior region of the plasma generator, neutral particles and/or radicals of the inductive plasma flow through a separation grid to the substrate within a processing chamber. Although a separation grid is shown in FIGS. 1 and 3, the method 1700 may be carried out without a separation grid.

At operation 1730, the substrate is processed within the process chamber. The temperature and pressure of the processing chamber can be controlled based on the particular substrate processing application. In general, the temperature may be about 200° C. to about 1200° C., and the pressure may be about 0.25 Torr to about 5 Torr. However, other temperatures and pressures are contemplated. The substrate in the processing chamber may be exposed to neutral particles and/or radicals generated in the inductive plasma that pass through the separation grid. In particular neutral particles and/or radicals contact a first side of the substrate facing the plasma generator. In some embodiments, the substrate is heated using a plurality of lamps disposed opposite the first side of the substrate. The neutral particles and/or radicals can be used, for instance, as part of a surface treatment process of the substrate. In practice, gas flow rates and/or gas ratios may be selected so that the surface of the substrate is saturated with the reactant supply of neutral particles and/or radicals. The capability of the apparatus disclosed herein to provide for surface saturation of the reactive species is attributed to a very high density source and a shortened distance between the plasma generator and the substrate.

In plasma processing operations without surface saturation, the arrival rate of the reactive species to the substrate surface determines the rate of reaction and/or incorporation of the reactive species. However, using apparatus and/or methods disclosed herein, reactive species are saturated on the surface due to high species flux such that diffusion of the reactive species becomes the dominating factor. Since temperature determines the diffusion of the reactive species and drives the reaction, the reaction is temperature-dependent. Because thermal energy is conformal in nature, being substantially uniform in three-dimensions, methods disclosed herein, which are controlled based on temperature, produce a more conformal surface treatment compared to plasma processing operations in which the arrival rate of the reactive species is rate determining.

The plasma can be generated by energizing one or more induction coils proximate the plasma generator with RF energy to generate a plasma using a process gas introduced into the plasma generator. For instance, process gas can be admitted into the plasma generator from a gas source. RF energy from RF source(s) can be applied to induction coil(s) to generate a plasma in the plasma generator.

In general, the method 1700 can be used for an array of different substrate processing applications including without limitation, nitrogen radical treatment (e.g., nitridation), oxygen radical treatment (e.g., oxidation), hydrogen radical treatment, helium radical treatment, and various pre- and post-treatments.

In summation, described herein are apparatuses related to plasma processing that may be utilized for processing a substrate. The plasma processing apparatus includes a processing chamber including a substrate support operable to hold a substrate, a main plasma source coupled with the processing chamber, a plate, a cavity, and an edge plasma generator. The cavity is housed within the plate and spaced radially outward from a dielectric sidewall of the main plasma source. The edge plasma generator is utilized to enhanced plasma processing at the edge of a substrate. The edge plasma source can be a dielectric barrier discharge (DBD) plasma generator, an inductively coiled plasma (ICP) plasma generator, or a capacitive coupled plasma (CCP) plasma generator.

As used herein, the terms “inner” and “outer”; “up” and “down”; “upper” and “lower”; “top” and “bottom”, “vertical” and “horizontal”, “upward” and “downward”; “above” and “below”; and other like terms as used herein refer to relative positions to one another and are not intended to denote a particular direction or spatial orientation of the overall source/apparatus. As used herein, the terms “approximately” or “about” refer to being within at least ±5% of the reference value.

While the foregoing is directed to embodiments of the present disclosure, other and further embodiments of the disclosure may be devised without departing from the basic scope thereof.

What is claimed is:

1. A plasma processing apparatus comprising:
a processing chamber including a substrate support operable to hold a substrate;
a main plasma source coupled with the processing chamber;
a plate;
a cavity housed within the plate and spaced radially outward from a dielectric sidewall of the main plasma source; and
an edge plasma generator.

2. The plasma processing apparatus of claim 1, the edge plasma generator further comprises:
a field concentrator comprising an inner side portion and an outer side portion, wherein the inner side portion is spaced radially inward from the cavity and the outer side portion is spaced radially outward from the cavity; and
an insulator comprising an inner side portion and an outer side portion, wherein the inner side portion is spaced radially inward from the cavity and radially outward from the inner side portion of the field concentrator, and the outer side portion is spaced radially outward from the cavity and radially inward from the outer side portion of the field concentrator.

3. The plasma processing apparatus of claim 2, wherein the field concentrator includes a ferromagnetic material.

4. The plasma processing apparatus of claim 3, wherein the ferromagnetic material has an upper frequency range greater than 2 MHz.

5. The plasma processing apparatus of claim 1, wherein the edge plasma generator uses a power supply with a frequency between 1 MHz and 15 MHz.

6. The plasma processing apparatus of claim 1, wherein the edge plasma generator further comprises a flux reducer positioned below the cavity.

7. A plasma processing apparatus comprising:
a processing chamber including a substrate support operable to hold a substrate;
a main plasma source coupled with the processing chamber; the main plasma source comprising:
an induction coil;
a dielectric sidewall;
a top cover; and
a main plasma source interior defined by the dielectric sidewall and top cover;
an edge plasma generator, the edge plasma generator comprising a first electrode;
a plate; and
a cavity housed within the plate and spaced radially outward from the dielectric sidewall, wherein the first electrode is disposed within or adjacent to the cavity.

8. The plasma processing apparatus of claim 7, wherein the first electrode is a capacitive coupled plasma (CCP) generator.

9. The plasma processing apparatus of claim 8, wherein the first electrode is circular and having a plurality of cuts along the electrode every 15° to 30°.

10. The plasma processing apparatus of claim 8, wherein a portion of the first electrode that is within the cavity is covered in a coating.

11. The plasma processing apparatus of claim 8, wherein an inner edge of the cavity is defined by an inner sidewall and an outer edge of the cavity is defined by an outer sidewall.

12. The plasma processing apparatus of claim 7, further comprising a second electrode, wherein the first electrode and the second electrode form a dielectric barrier discharge (DBD) plasma generator.

13. The plasma processing apparatus of claim 12, wherein the first electrode and the second electrode are a circular having a plurality of cuts along the first electrode and second electrode every 15° to 30°.

14. The plasma processing apparatus of claim 12, wherein a portion of the first electrode that is within the cavity is covered in a coating.

15. The plasma processing apparatus of claim 12, wherein a top, an inner side, and an outer side of the cavity is defined by a cavity conduit having an inner side portion, an outer side portion, and a top portion.

16. A plasma processing apparatus comprising:
a processing chamber including a substrate support operable to hold a substrate;
a main plasma source coupled with the processing chamber; the main plasma source comprising:
an induction coil;
a dielectric sidewall;
a top cover; and
a main plasma source interior defined by the dielectric sidewall and top cover;
a plate;
a plurality of apertures housed within the plate and spaced radially outward from the dielectric sidewall; and
an edge plasma generator, the edge plasma generator comprising a first electrode disposed within or adjacent to the apertures.

17. The plasma processing apparatus of claim 16, wherein the first electrode is a capacitive coupled plasma (CCP) generator.

18. The plasma processing apparatus of claim 17, wherein a first portion of the electrode is surrounded by a coating and an electrode conduit radially surrounds the aperture, wherein the electrode radially surrounds the aperture within the electrode conduit.

19. The plasma processing apparatus of claim 16, further comprising a second electrode, wherein the first electrode and the second electrode form a dielectric barrier discharge (DBD) plasma generator.

20. The plasma processing apparatus of claim 19, wherein a first portion of the first electrode is surrounded by a first coating, a first portion of the second electrode is surrounded by a second coating, and an electrode conduit, wherein the electrode conduit surrounds a portion of the aperture, and wherein a second portion of the first electrode and a second portion of the second electrode radially surround the aperture within the electrode conduit.
